(19) United States
(12) Patent Application Publication
(10) Pub. No.: US 2008/0197846 A1
(43) Pub. Date: Aug. 21, 2008

(54) Magnetic Resonance Imaging With Several Types of Contrast

(75) Inventors: Romhild Martijn Hoogeveen, Eindhoven (NL); Jan Frans Lodewijk De Becker, Eindhoven (NL); Peter Boernert, Hamburg (DE); Johannes Adrianus Overweg, Uelzen (DE)

Correspondence Address: PHILIPS INTELLECTUAL PROPERTY & STANDARDS, 595 MINER ROAD, CLEVELAND, OH, 44143, US

(73) Assignee: KONINKLIJKE PHILIPS ELECTRONICS N. V., Eindhoven (NL)

(21) Appl. No.: 12/066,269

(22) PCT Filed: Sep. 8, 2006
(86) PCT No.: PCT/IB2006/053167

§ 371 Date: Mar. 10, 2008

(30) Foreign Application Priority Data
Sep. 15, 2005 (EP) 05108485.3

(51) Int. Cl. G01R 33/54

(52) U.S. Cl. 324/309

(57) ABSTRACT

A magnetic resonance imaging system comprises a signal acquisition system to acquire magnetic resonance signals. A reconstructor reconstructs magnetic resonance images from the acquired magnetic resonance signals. The signal acquisition system and/or the reconstructor are controlled to perform overhead activities separately from actual acquisition of the magnetic resonance signals notably for different contrast types. Accordingly, time efficient signal acquisition for multiple contrasts is achieved.

The invention pertains to a magnetic resonance imaging system having a signal acquisition system to acquire magnetic resonance signals and a reconstructor to reconstruct magnetic resonance images from the magnetic resonance signals.

Such a magnetic resonance imaging system is known from the international application WO98/46132.

The cited prior art document mentions that the MRI data acquisition process is triggered while the patient holds his or her breath. In this way motion artifacts due to breathing motion are avoided in the magnetic resonance image. The known magnetic resonance imaging system is further arranged to add dead-time intervals during the signal acquisition process in order to allow the patient to exhale and inhale and resume the signal acquisition during the subsequent breath-hold. In this way, the performance of the known magnetic resonance imaging system is not restricted by the interval during which the patient to be examined is able to hold his or her breath. However, the introduction of additional dead time intervals increases to total scan time required to generate the magnetic resonance image.

An object of the invention is to provide a magnetic resonance imaging system in which the time-span required for data acquisition is reduced.

This object is achieved in the magnetic resonance imaging system of the invention comprising
signal acquisition system to acquire magnetic resonance signals
a reconstructor to reconstruct one or more magnetic resonance images from the acquired magnetic resonance signals and
a controller to control the signal acquisition system and the reconstructor wherein
the controller is arranged to
   control the signal acquisition system and/or the reconstructor to perform overhead activities separately from actual acquisition of the magnetic resonance signals.

The separation of overhead activities from the actual signal acquisition achieves that the actual signal acquisition is performed more time-efficient. That is, either a given amount of magnetic resonance signals can be acquired during a shorter time interval or during a given interval of time more magnetic resonance signals can be acquired. In particular during an individual breath-hold of the patient to be examined a relative large amount of magnetic resonance signals can be acquired. This reduces the risk of the occurrence of breathing motion artefacts in the magnetic resonance image, or even the risk is less to have to re-scan in the event a too much motion occurred during signal acquisition.

These and other aspects of the invention will be further elaborated with reference to the embodiments defined in the dependent Claims.

The overhead activities concern preparation steps that need to be performed prior to the signal acquisition. In practice, these preparation steps include for example the adjustment of the central demodulation frequency (f₀-determination), setting receiver gain and optimisation of the flip angle in steady-state MR acquisition sequences (e.g. balanced FFE). The overhead activities for example further concern any (partial) reconstruction activities and/or (inverse) Fourier transformation of the acquired magnetic resonance signals or unfolding of aliases magnetic resonance signals. Also included in the overhead activities are scan completion processes that are involved in closing of the imaging process. These scan completion process include for example logging of scan parameters, writing image data to disc or (re-)allocation of memory. According to a particular aspect of the invention, the signal acquisition includes acquisition of (sets of) magnetic resonance signals pertaining to respective different image contrasts. The overhead activities relating to these acquisitions of different contrast are separated from the actual signal acquisitions. Hence, signal acquisitions of different contrasts can be performed in a shorter time interval, notably within a patient's breath-hold. The time interval required is shorter, or in a given time interval more (sets of) magnetic resonance signals can be acquired as the overhead activities are separated from the signal acquisition to a larger extent. That is, already an appreciable improvement of the time efficiency of the signal acquisition is achieved already when a substantial part of the overhead activities are separate from the signal acquisition. In some instances leaving a minor portion of the preparation may be left to be carried out within the signal acquisition time span.

According to a further aspect of the invention, reconstruction of several magnetic resonance image from the acquired magnetic resonance signals is performed in parallel. In this way, during actual signal acquisition magnetic resonance signals representing different contrast types, such as e.g. T₁-contrast and T₂-contrast are acquired. After the actual signal acquisition, the respective magnetic resonance images of different contrasts are reconstructed in a parallel way. That is, the respective different magnetic resonance images are reconstructed simultaneously from the respective sets of magnetic resonance signals that carry the different contrast information. Acquiring magnetic resonance signals for respective different contrasts during a single breath-hold further reduces the need for correcting misregistration of cross-sectional slices between different breath-holds.

According to another aspect of the invention, the preparation steps are performed separate from the actual signal acquisition, such that no time is lost for this overhead during the time-critical acquisition windows. An example is to obtain a T₁ and a T₂-contrast scan in a breath hold with the preparation steps performed separately in another breath hold, before the T₁ and the T₂ scan. Reconstruction is suspended until after the breath hold or parallelised. In this way, the invention enables to perform multiple scans (e.g. in a breath hold) with no time lost during the actual signal acquisition for the overhead of these scans. Preferably, the preparation steps are performed under equal circumstances as compared to the actual signal acquisition the preparation steps are associated with. This achieves that the preparation accurately corresponds to the signal acquisition, notably the preparation accurately relates to the same portion (e.g. cross sectional slice or slab) of the patient to be examined from which magnetic resonance signals are acquired.

The invention also relates to a magnetic resonance imaging method as defined in the method Claim. This magnetic resonance imaging method of the invention achieves to more time-efficiently acquire magnetic resonance signals. The invention further relates to a computer programme as defined in the computer programme Claim. De computer programme of the invention can be provided on a data carrier such as a CD-rom disk, or the computer programme of the invention can be downloaded from a data network such as the worldwide web. When installed in the computer included in a magnetic resonance imaging system the magnetic resonance imaging system is enabled to operate according to the invention and achieve more time-efficient acquisition of magnetic resonance signals.

These and other aspects of the invention will be elucidated with reference to the embodiments described hereinafter and with reference to the accompanying drawing wherein

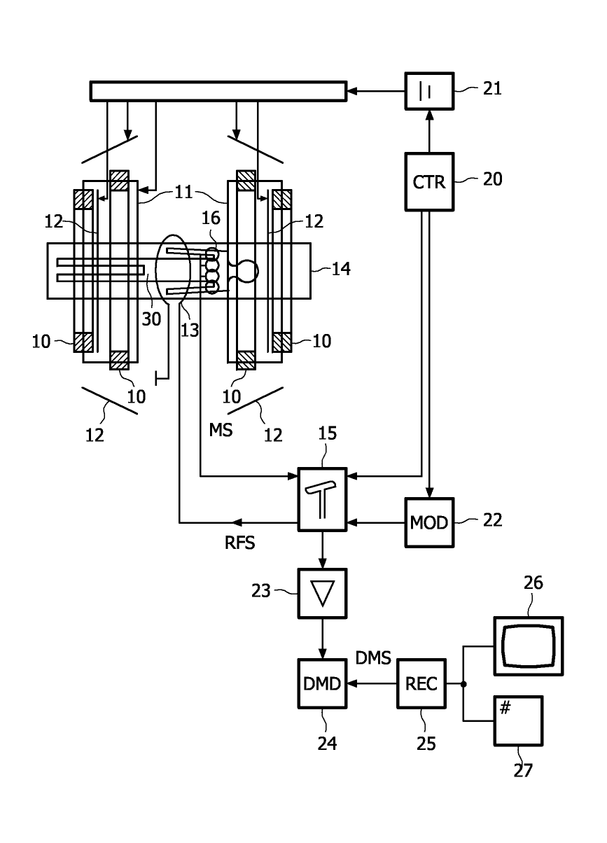

The FIG. 1 shows diagrammatically a magnetic resonance imaging system in which the invention is used.

The FIG. 1 shows diagrammatically a magnetic resonance imaging system in which the invention is used. The magnetic resonance imaging system includes a set of main coils 10 whereby the steady, uniform magnetic field is generated. The main coils are constructed, for example in such a manner that they enclose a tunnel-shaped examination space. The patient to be examined is placed on a patient carrier, which is slid into this tunnel-shaped examination space. The magnetic resonance imaging system also includes a number of gradient coils 11, 12 whereby magnetic fields exhibiting spatial variations, notably in the form of temporary gradients in individual directions, are generated so as to be superposed on the uniform magnetic field. The gradient coils 11, 12 are connected to a controllable power supply unit 21. the gradient coils 11, 12 are energised by application of an electric current by means of the power supply unit 21; to this end the power supply unit is fitted with electronic gradient amplification circuit that applies the electric current to the gradient coils so as to generate gradient pulses (also termed ‘gradient waveforms’) of appropriate temporal shape The strength, direction and duration of the gradients are controlled by control of the power supply unit. The magnetic resonance imaging system also includes transmission and receiving coils 13, 16 for generating the RF excitation pulses and for picking up the magnetic resonance signals, respectively. The transmission coil 13 is preferably constructed as a body coil 13 whereby (a part of) the object to be examined can be enclosed. The body coil is usually arranged in the magnetic resonance imaging system in such a manner that the patient 30 to be examined is enclosed by the body coil 13 when he or she is arranged in the magnetic resonance imaging system. The body coil 13 acts as a transmission antenna for the transmission of the RF excitation pulses and RF refocusing pulses. Preferably, the body coil 13 involves a spatially uniform intensity distribution of the transmitted RF pulses (RFS). The same coil or antenna is usually used alternately as the transmission coil and the receiving coil. Furthermore, the transmission and receiving coil is usually shaped as a coil, but other geometries where the transmission and receiving coil acts as a transmission and receiving antenna for RF electromagnetic signals are also feasible. The transmission and receiving coil 13 is connected to an electronic transmission and receiving circuit 15.

It is to be noted that it is alternatively possible to use separate receiving and/or transmission coils 16. For example, surface coils 16 can be used as receiving and/or transmission coils. Such surface coils have a high sensitivity in a comparatively small volume. The receiving coils, such as the surface coils, are connected to a demodulator 24 and the received magnetic resonance signals (MS) are demodulated by means of the demodulator 24. The demodulated magnetic resonance signals (DMS) are applied to a reconstruction unit. The receiving coil is connected to a preamplifier 23. The preamplifier 23 amplifies the RF resonance signal (MS) received by the receiving coil 16 and the amplified RF resonance signal is applied to a demodulator 24. The demodulator 24 demodulates the amplified RF resonance signal. The demodulated resonance signal contains the actual information concerning the local spin densities in the part of the object to be imaged. Furthermore, the transmission and receiving circuit 15 is connected to a modulator 22. The modulator 22 and the transmission and receiving circuit 15 activate the transmission coil 13 so as to transmit the RF excitation and refocusing pulses. The reconstruction unit derives one or more image signals from the demodulated magnetic resonance signals (DMS), which image signals represent the image information of the imaged part of the object to be examined. The reconstruction unit 25 in practice is constructed preferably as a digital image-processing unit 25 which is programmed so as to derive from the demodulated magnetic resonance signals the image signals which represent the image information of the part of the object to be imaged. The signal on the output of the reconstruction monitor 26, so that the monitor can display the magnetic resonance image. It is alternatively possible to store the signal from the reconstruction unit 25 in a buffer unit 27 while awaiting further processing.

The magnetic resonance imaging system according to the invention is also provided with the controller in the form of a control unit 20, for example in the form of a computer which includes a (micro)processor. The control unit 20 controls the execution of the RF excitations and the application of the temporary gradient fields. To this end, the computer program according to the invention is loaded, for example, into the control unit 20 and the reconstruction unit 25.

An illustrative example of the implementation of the invention is now discussed. As an example two different 3D imaging sequences with Cartesian k-space sampling, should be considered. Thus, a 3D Balanced-FFE (B-FFE) and a 3D TSE, were concatenated during the breath-hold. In both sequences, SENSE was used in both phase-encoding directions. Thus, SENSE made optimal use of the distribution of the coil elements over the body.

The 3D B-FFE used the following parameters: SENSE-factor 16 (8/4×RL, 4×FH), FOV 520×260, Scan Matrix 384×192, 160 transversal slices of 2 mm, TR/TE/Flip=4.7 ms/2.3 ms/60′, Scan Time 10 sec. The FH-coverage was 320 mm. The 3D TSE sequence used the following parameters: SENSE-factor 16 (4×RL, 4×FH), FOV 520×260, Scan Matrix 384×192, 40 transversal slices of 6 mm, TR/TE=277 ms/60 ms, TSE factor 35, Halfscan 0.725, Scan Time 10 sec. The FH-coverage was 240 mm. The total imaging time of the two sequences in both series was about 20 seconds, and performed during one breath-hold.

The coil used consists of two 4×4 grids of identical rectangular of 10×11 cm² coil elements. The coil is designed such that it has enough flexibility to wrap it around the patient, allowing improved signal receiving. The coil is attached to a 32 channel receive system of an MR scanner. SENSE-factors (up to 32) allow larger volumetric coverage than currently used sequences with SENSE-factors up to 2. Combining multiple contrasts in one breath-hold can be a major breakthrough in abdominal MRI. The number of breath-holds for a patient can be severely reduced leading to an increased patient comfort and allowing significantly shorter examination times. Acquiring multiple contrasts in one breath-hold improves the problem of possible misregistration of slices between different breath-holds. This will facilitate diagnostic reading as well as segmentation methods based on multi-parametric data. The invention is also applicable to T1_{w}-FFE and fat suppressed sequences.

The contrast scan may also include a contrast-enhanced scan, so during or after the injection of a contrast agent.

1. A magnetic resonance imaging system comprising
a signal acquisition system is arranged to acquire sets of magnetic resonance signals representing respective different contrasts
a reconstructor to reconstruct one or more magnetic resonance images from the acquired magnetic resonance signals and
a controller to control the signal acquisition system and the reconstructor wherein
the controller is arranged to
control the signal acquisition system and/or the reconstructor to perform overhead activities relating to said contrasts separately from the actual acquisition of the sets of magnetic resonance signals representing respective different contrasts.

2. (canceled)

3. A magnetic resonance imaging system as claimed in claim 1, wherein the overhead activities include preparations of the signal acquisition system prior to the actual acquisition of the magnetic resonance signals.

4. A magnetic resonance imaging system as claimed in claim 1, wherein the overhead activities include reconstruction of image data from the acquired magnetic resonance signals.

5. A magnetic resonance imaging system as claimed in claim 3, wherein
the controller is arranged to control the imaging process of setting the signal acquisition system, acquiring magnetic resonance signals, reconstructing one or more image(s)
the overhead activities include closing of the imaging process of setting the signal acquisition system, acquiring magnetic resonance signals and reconstructing the magnetic resonance image(s).

6. A magnetic resonance imaging system as claimed in claim 1, wherein the controller is arranged to suspend and/or parallelise
(i) reconstruction of several magnetic resonance images until after acquisition of the magnetic resonance signals for that/those magnetic resonance image(s) have been completed and/or
(ii) closing of the imaging processes of the respective magnetic resonance images.

7. A magnetic resonance imaging system as claimed in claim 1, wherein the controller is arranged to suspend
(i) signal acquisitions until after preparations of the magnetic resonance signals of one or more magnetic resonance image(s) has/have been completed and/or
(ii) closing of the imaging processes of the respective magnetic resonance images.

8. A magnetic resonance imaging system as claimed in claim 1, wherein the controller is arranged to carry out the preparation of the signal acquisition and the actual signal acquisition under equal circumstances.

9. A magnetic resonance imaging method comprising
acquiring magnetic resonance signals representing respective different contrasts
reconstruct one or more magnetic resonance images from the acquired magnetic resonance signals and
control the signal acquisition and the reconstruction wherein
the signal acquisition and/or the reconstruction are controlled to perform overhead activities relating to said contrasts separately from the actual acquisition of the sets of magnetic resonance signals representing respective different contrasts.

10. A computer programme comprising instruction to
control signal acquisition of magnetic resonance signals representing respective different contrasts and reconstruction of a magnetic resonance image wherein
the signal acquisition and/or the reconstruction are controlled to perform overhead activities relating to said contrasts separately from the actual acquisition of the sets of magnetic resonance signals representing respective different contrasts.
